(19) United States
(12) Patent Application Publication
(10) Pub. No.: US 2018/0180999 A1
(43) Pub. Date: Jun. 28, 2018

(54) IMPRINT MATERIAL

(71) Applicant: NISSAN CHEMICAL INDUSTRIES, LTD., Tokyo (JP)

(72) Inventors: Junpei KOBAYASHI, Funabashi-shi (JP); Taku KATO, Funabashi-shi (JP); Keisuke SHUTO, Funabashi-shi (JP); Masayoshi SUZUKI, Funabashi-shi (JP)

(73) Assignee: NISSAN CHEMICAL INDUSTRIES, LTD., Tokyo (JP)

(21) Appl. No.: 15/740,285

(22) PCT Filed: May 31, 2016
(86) PCT No.: PCT/JP2016/066010

§ 371 Date: Dec. 27, 2017

(30) Foreign Application Priority Data
Jun. 29, 2015 (JP) 2015-129861

(51) Int. Cl. G03F 7/038; G03F 9/00; C08F 2/44; C08F 2/48; C08L 33/10; C08L 33/08; C08L 33/26

(52) U.S. Cl. CPC G03F 7/0388; G03F 9/7042; C08F 2/44; C08L 2203/16; C08L 33/10; C08L 33/08; C08L 33/26; C08F 2/48

(57) ABSTRACT

A novel imprint material including a component (A); a component (B); a component (C); and a component (D) below. (A): a compound of Formula (1) below, (B): a compound of Formula (2) below, (C): a compound of Formula (3) below, and (D): a photopolymerization initiator,

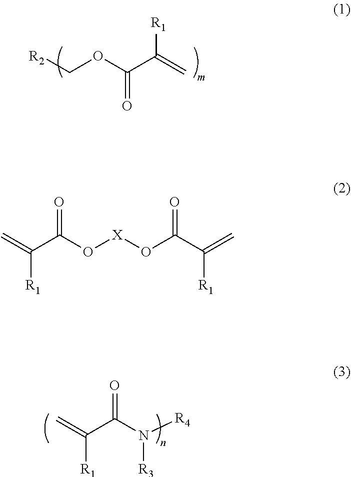

wherein, each R₁ is independently a hydrogen atom or a methyl group, R₂ is a C₁₋₅ hydrocarbon group that optionally has a hydroxy group as a substituent, m is 2 or 3, X is a divalent linking group having an ethylene oxide unit and/or a propylene oxide unit, R₃ is a hydrogen atom or a C₁₋₃ alkyl group, n is 1 or 2, and when n is 1, R₄ is a C₁₋₁₂ alkyl group that is optionally substituted with at least one substituent, and when n is 2, R₄ is a C₁₋₁₂ alkylene group that is optionally substituted with at least one substituent.

### TECHNICAL FIELD

The present invention relates to an imprint material (a composition for forming a film for imprint) and a film produced from the material, on which a pattern is transferred. More specifically, the present invention relates to a film that is produced from the material, on which a pattern is transferred, and that is excellent in wiping performance on a surface thereof, adherence to a substrate, and abrasion resistance.

### BACKGROUND ART

In 1995, Professor Chou who is currently at Princeton University and others developed a novel technology called nanoimprint lithography (Patent Document 1). The nanoimprint lithography is a technology in which a mold having any pattern is caused to contact with a base material on which a resin film is formed; and pressure is applied to the resin film while applying an external stimulation of heat or light to form a desired pattern on the cured resin film. The nanoimprint lithography makes simple and low-cost nanoscale processes available, and thus is advantageous compared to photolithography and the like used for conventional manufacture of semiconductor devices.

The nanoimprint lithography is expected to be applied to manufacture of semiconductor devices, optical devices, displays, storage media, biochips, and the like, instead of photolithography, and thus various reports about curable compositions for photonanoimprint lithography used for nanoimprint lithography have been published (Patent Documents 2 and 3).

As a method for mass-producing pattern-transferred films with high efficiency in photo-nanoimprint lithography, roll-to-roll processing has been proposed. In the roll-to-roll processing conventionally proposed for photo-nanoimprint lithography, prevalent methods each use a flexible film as a base material and use, as a material used for nanoimprint lithography (hereinafter, abbreviated as “imprint material”), a solvent-free material in which a solvent is not added so that the pattern dimensions are difficult to change.

### PRIOR ART DOCUMENTS

### Patent Documents

Patent Document 1: U.S. Pat. No. 5,772,905 (U.S. Pat. No. 5,772,905 B2)

Patent Document 2: Japanese Patent Application Publication No. 2008-105414 (JP 2008-105414 A)

Patent Document 3: Japanese Patent Application Publication No. 2008-202022 (JP 2008-202022 A)

### SUMMARY OF THE INVENTION

### Problem to be Solved by the Invention

As described above, solvent-free materials are used for the conventionally proposed imprint material, but there is a situation in which preferable adherence cannot be obtained between a film after imprinting and a base material film. In products such as solid-state image sensing devices, solar cells, LED devices, and displays, concavity and convexity shapes formed therein or on surfaces thereof as optical components may be required to have abrasion resistance. Furthermore, when such concavity and convexity shapes are formed on surfaces of the products described above, dirt is removed from the surfaces by damp-cloth wiping, and adjacent convex portions in the concavity and convexity shapes need to be prevented from adhering to each other during the dirt removal. However, although various types of imprint materials have been disclosed, materials that have sufficient adherence to film base materials and excellent abrasion resistance and do not allow the adjacent convex portions to adhere to each other during damp-cloth wiping have not been specifically studied or reported.

The present invention has been made based on the above circumstances, and an object thereof is to provide an imprint material for forming a film that has sufficient adherence to a film base material and excellent abrasion resistance and does not allow adjacent convex portions to adhere to each other during damp-cloth wiping when the imprint material is used to form a resin film.

### Means for Solving the Problem

As a result of intensive studies to solve the problems described above, the present inventors obtained findings described below and completed the present invention. By using, as an imprint material, a material that contains a predetermined compound having polymerizable groups on its ends, a compound having a propylene oxide unit and/or an ethylene oxide unit and having polymerizable groups on its ends, a predetermined (meth)acrylamide compound, and a photopolymerization initiator, adherence between a film on which a concavity and convexity shape is transferred and a base material is excellent, a surface of the film on which the concavity and convexity shape is transferred is substantially prevented from being scratched in a steel-wool abrasion test, and adjacent convex portions in the concavity and convexity shape are prevented from adhering to each other even when the surface on which the concavity and convexity shape is transferred is wiped with a damp cloth.

As a first aspect, the present invention relates to an imprint material comprising: a component (A); a component (B); a component (C); and a component (D) below.

(A): a compound of Formula (1) below,

(B): a compound of Formula (2) below,

(C): a compound of Formula (3) below, and

(D): a photopolymerization initiator.

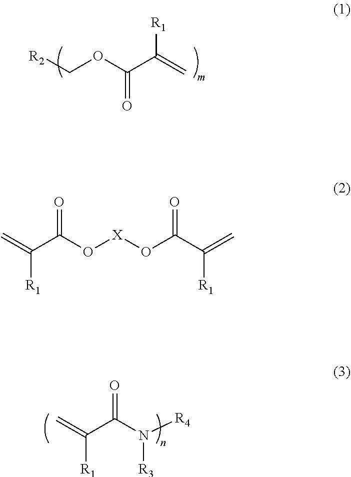

(wherein, each R₁ is independently a hydrogen atom or a methyl group, R₂ is a C₁₋₅ hydrocarbon group that optionally has a hydroxy group as a substituent, m is 2 or 3, X is a divalent linking group having an ethylene oxide unit and/or a propylene oxide unit, R₃ is a hydrogen atom or a C₁₋₃ alkyl group, n is 1 or 2, and

when n is 1, R₄ is a C₁₋₁₂ alkyl group that is optionally substituted with at least one substituent selected from the group consisting of hydroxy group, carboxy group, acetyl group, amino group in which one or two hydrogen atoms are optionally substituted with a methyl group, sulfo group, and a C₁₋₄ alkoxy group, and

when n is 2, R₄ is a C₁₋₁₂ alkylene group that is optionally substituted with at least one substituent selected from the group consisting of hydroxy group, carboxy group, acetyl group, amino group in which one or two hydrogen atoms are optionally substituted with a methyl group, sulfo group, and a C₁₋₄ alkoxy group).

As a second aspect, the present invention relates to the imprint material according to the first aspect, in which the component (B) contains one or two compounds of Formula (2a):

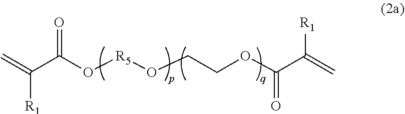

(wherein, each R₁ is independently a hydrogen atom or a methyl group, R₅ is a trimethylene group or a propylene group, and each of p and q is independently an integer of 0 or more and satisfies a relational expression of 1≤(p+q)≤30).

As a third aspect, the present invention relates to the imprint material according to the first aspect or the second aspect, in which content of the component (A) is 10% by mass or higher and 40% by mass or lower, based on total mass of the component (A), the component (B), and the component (C).

As a fourth aspect, the present invention relates to the imprint material according to the first aspect or the second aspect, in which content of the component (C) is 1% by mass or higher and 40% by mass or lower, based on total mass of the component (A), the component (B), and the component (C).

As a fifth aspect, the present invention relates to the imprint material according to any one of the first aspect to the fourth aspect further comprising a silicone compound as a component (E).

As a sixth aspect, the present invention relates to the imprint material according to any one of the first aspect to the fifth aspect further comprising a surfactant as a component (F).

As a seventh aspect, the present invention relates to the imprint material according to any one of the first aspect to the sixth aspect further comprising a solvent as a component (G).

As an eighth aspect, the present invention relates to a method for producing a film on which a pattern is transferred, the method comprising: a step of forming a film by applying the imprint material according to any one of the first aspect to the seventh aspect onto a base material; and a step of transferring the pattern onto the film by using a photoimprint device, bringing a mold on which a pattern is formed into contact with the film, further pressing the film against the mold, subsequently light-curing the film, and then releasing the mold from the film.

### Effects of the Invention

The imprint material of the present invention contains a predetermined compound having polymerizable groups on its ends, a compound having a propylene oxide unit and/or an ethylene oxide unit and having polymerizable groups on its ends, and a predetermined (meth)acrylamide compound. Thus, a cured film produced from the imprint material has sufficient adherence to a film base material, and the cured film also has excellent abrasion resistance. Even when a surface of the cured film on which a concavity and convexity shape is transferred is wiped with a damp cloth, adjacent convex portions in the concavity and convexity shape are prevented from adhering to each other.

Also, light curing is applicable to the imprint material of the present invention, and when a film is peeled from the surface of a mold, a portion of a pattern will not be peeled, and thus a film on which a desired pattern is accurately formed can be obtained. Accordingly, a good photoimprint pattern can be formed.

The imprint material of the present invention can form films on any base materials, a film thus formed has sufficient adherence to a film base material, and the film has abrasion resistance. Furthermore, when a surface of the film on which a concavity and convexity shape is transferred is wiped with a damp cloth, adjacent convex portions in the concavity and convexity shape are prevented from adhering to each other. Thus, a pattern-transferred film formed after imprinting can be suitably used to produce optical components requiring abrasion resistance and resistance to damp-cloth wiping, such as solid-state image sensing devices, solar cells, LED devices, and displays.

In addition, the imprint material of the present invention can control a cure rate, dynamic viscosity, and the film thickness, by selecting types and percentages of the compounds of the component (B). Accordingly, by using the imprint material of the present invention, a material can be designed in accordance with the type of a device to be manufactured, and in accordance with the types of an exposure process and a baking process. Thus, the imprint material of the present invention can expand a process margin, and can suitably be used for manufacturing optical components.

### MODES FOR CARRYING OUT THE INVENTION

[Component (A): Compound of Formula (1)]

The compound of the component (A) is a compound of Formula (1):

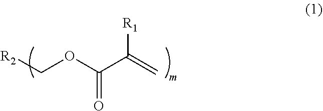

(wherein, R¹ is a hydrogen atom or a methyl group, R₂ is a C₁₋₅ hydrocarbon group that optionally has a hydroxy group as a substituent, and m is 2 or 3).

Specific examples of the compound of Formula (1) include trimethylolpropane triacrylate, pentaerythritol triacrylate, trimethylolpropane trimethacrylate, and pentaerythritol trimethacrylate.

The compounds of Formula (1) are commercially available, and specific examples thereof include NK ester 701A, NK ester 701, NK ester A-HD-N, NK ester A-NPG; NK ester NPG, NK ester A-TMPT, and NK ester TMPT (all of the above, manufactured by Shin Nakamura Chemical Co., Ltd.); ARONIX (registered trademark) M309 (manufactured by Toagosei Co., Ltd.); and KAYARAD NPGDA and KAYARAD TMPTA (all of the above, manufactured by Nippon Kayaku Co., Ltd.).

The compound of the component (A) can be used alone, or two or more types can be used in combination.

The content of the component (A) in the imprint material of the present invention is preferably 10% by mass or higher and 40% by mass or lower, based on the total mass of the component (A) and components (B) and (C) described later. If the content of the component (A) is lower than 10% by mass, when a film obtained by photoimprint is wiped with a damp cloth, structures thereof are likely to adhere to each other. If the component (A) is added at a content higher than 40% by mass, abrasion resistance significantly decreases.

[Component (B): Compound of Formula (2)]

The compound of the component (B) is a compound of Formula (2):

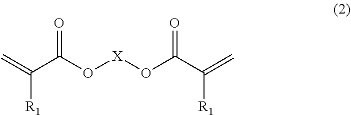

(wherein, each R¹ is independently a hydrogen atom or a methyl group, and X is a divalent linking group having an ethylene oxide unit and/or a propylene oxide unit).

Herein, the propylene oxide unit is (—CH(CH₃)CH₂O—) or (—CH₂CH₂CH₂O—), for example, and the ethylene oxide unit is (—CH₂CH₂O—), for example.

Among the compounds of Formula (2), examples of a compound having one or more ethylene oxide units in one molecule include ethylene glycol di(meth)acrylate, polyethylene glycol di(meth)acrylates, ethoxylated bisphenol A di(meth)acrylate, and isocyanuric acid ethylene oxide-modified diacrylate. Note that the (meth)acrylate compound herein refers to both an acrylate compound and a methacrylate compound. For example, (meth)acrylic acid refers to acrylic acid and methacrylic acid.

Among the compounds of Formula (2), the compound having one or more ethylene oxide units in one molecule is commercially available, and specific examples thereof include NK ester A-200, NK ester A-400, NK ester A-600, NK ester A-1000, NK ester 1G, NK ester 2G, NK ester 3G, NK ester 4G, NK ester 9G, NK ester 14G, NK ester 23G; NK ester ABE-300, NK ester A-BPE-4, NK ester A-BPE-6, NK ester A-BPE-10, NK ester A-BPE-20, NK ester A-BPE-30, NK ester BPE-80N, NK ester BPE-100N, NK ester BPE-200, NK ester BPE-500, NK ester BPE-900, and NK ester BPE-1300N, (all of the above, manufactured by Shin Nakamura Chemical Co., Ltd.); KAYARAD (registered trademark) PEG400DA (all of the above, manufactured by Nippon Kayaku Co., Ltd.); and ARONIX (registered trademark) M-215 (manufactured by Toagosei Co., Ltd.).

Among the compounds of Formula (2), examples of a compound having one or more propylene oxide units in one molecule include dipropylene glycol di(meth)acrylate, tripropylene glycol di(meth)acrylate, polypropylene glycol #400 di(meth)acrylates, and polypropylene glycol #700 di(meth)acrylates.

Among the compounds of Formula (2), the compound having one or more propylene oxide units in one molecule is commercially available, and specific examples thereof include NK ester APG-100, APG-200, APG-400, APG-700, 3PG, and 9PG (all of the above, manufactured by Shin Nakamura Chemical Co., Ltd.); and FANCRYL (registered trademark) FA-P240A and FANCRYL FA-P270A (all of the above, manufactured by Hitachi Chemical Co., Ltd.).

Among the compounds of Formula (2), examples of a compound having one or more ethylene oxide unit and one or more propylene oxide unit in one molecule include ethylene oxide propylene oxide copolymer di(meth)acrylic esters, propoxylated ethoxylated bisphenol A di(meth)acrylate, and ethoxylated polypropylene glycol #700 di(meth)acrylates.

Among the compounds of Formula (2), the compound having one or more ethylene oxide unit and one or more propylene oxide unit in one molecule is commercially available, and specific examples thereof include A-1000PER and A-B1206PE (all of the above, manufactured by Shin Nakamura Chemical Co., Ltd.); and FANCRYL (registered trademark) FA-023M (all of the above, manufactured by Hitachi Chemical Co., Ltd.).

The compound of the component (B) can be used alone, or two or more types can be used in combination. When the compound of the component (B) is used in combination of two or more types, examples of these compounds include, in a compound of Formula (2a):

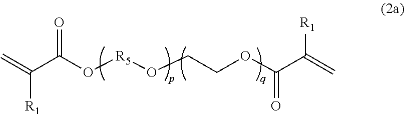

(wherein, each R₁ is independently a hydrogen atom or a methyl group, R₅ is a trimethylene group or a propylene group, and each of p and q is independently an integer of 0 or more and satisfies a relational expression of 1≤(p+q)≤30),

a combination of a compound in which p is 0 and q is an integer of 1 or more (i.e., having one or more ethylene oxide unit in one molecule) and a compound in which p is an integer of 1 or more and q is an integer of 1 or more (i.e., having one or more propylene oxide units and one or more ethylene oxide units in one molecule).

The content of the component (B) in the imprint material of the present invention is 5% by mass or higher and 80% by mass or lower, for example, and preferably 50% by mass or higher and 80% by mass or lower, based on the total mass of the components (A) and (B) and the later-described component (C).

The component (B) in the imprint material of the present invention can impart abrasion resistance to a pattern-transferred film. The component (B) helps a silicone compound of a component (E) described later to breed out during curing at the time of imprinting, and can reduce a mold release force measured when an obtained resin film (cured film) is detached from a mold surface. By changing the type and the content of the compound of the component (B), dynamic viscosity of the imprint material, a cure rate at the time of imprinting, and the thickness of a film to be formed can be controlled.

[Component (C): Compound of Formula (3)]

The compound of the component (C) is a compound of Formula (3) below, that is, a compound having a (meth)acrylamide structure in its structure.

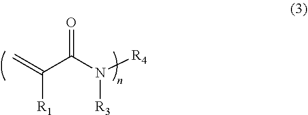

(wherein, R¹ is a hydrogen atom or a methyl group, R₃ is a hydrogen atom or a C₁₋₃ alkyl group, and n is 1 or 2, and

when n is 1, R⁴ is a C₁₋₁₂ alkyl group that is optionally substituted with at least one substituent selected from the group consisting of hydroxy group, carboxy group, acetyl group, amino group in which one or two hydrogen atoms are optionally substituted with a methyl group, sulfo group, and a C₁₋₄ alkoxy group, and

when n is 2, R⁴ is a C₁₋₁₂ alkylene group that is optionally substituted with at least one substituent selected from the group consisting of hydroxy group, carboxy group, acetyl group, amino group in which one or two hydrogen atoms are optionally substituted with a methyl group, sulfo group, and a C₁₋₄ alkoxy group).

The C₁₋₁₂ alkyl group may be any one of linear, branched, and cyclic alkyl groups, and specific examples thereof include methyl group, ethyl group, n-propyl group, isopropyl group, cyclopropyl group, n-butyl group, isobutyl group, sec-butyl group, tert-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, 2-ethyl-3-methyl-cyclopropyl group, n-heptyl group, n-octyl group, n-nonyl group, n-decyl group, n-undecyl group, and n-dodecyl group. Specific examples of the C₁₋₃ alkyl group include C₁₋₃ groups among the above-recited examples of the C₁₋₁₂ alkyl group.

Specific examples of the C₁₋₁₂ alkylene group may be any types of linear, branched, and cyclic ones, and specifically include methylene group, ethylene group, propane-1,2-diyl group, propane-1,3-diyl group, 2,2-dimethyl propane-1,3-diyl group, 2-ethyl-2-methyl propane-1,3-diyl group, 2,2-diethyl propane-1,3-diyl group, 2-methyl-2-propyl propane-1,3-diyl group, butane-1,3-diyl group, butane-2,3-diyl group, butane-1,4-diyl group, 2-methylbutane-2,3-diyl group, 2,3-dimethylbutane-2,3-diyl group, pentane-1,3-diyl group, pentane-1,5-diyl group, pentane-2,3-diyl group, pentane-2,4-diyl group, 2-methylpentane-2,3-diyl group, 3-methylpentane-2,3-diyl group, 4-methylpentane-2,3-diyl group, 2,3-dimethylpentane-2,3-diyl group, 3-methylpentane-2,4-diyl group, 3-ethylpentane-2,4-diyl group, 3,3-dimethylpentane-2,4-diyl group, 3,3-dimethylpentane-2,4-diyl group, 2,4-dimethylpentane-2,4-diyl group, hexane-1,6-diyl group, hexane-1,2-diyl group, hexane-1,3-diyl group, hexane-2,3-diyl group, hexane-2,4-diyl group, hexane-2,5-diyl group, 2-methylhexane-2,3-diyl group, 4-methylhexane-2,3-diyl group, 3-methylhexane-2,4-diyl group, 2,3-dimethylhexane-2,4-diyl group, 2,4-dimethylhexane-2,4-diyl group, 2,5-dimethylhexane-2,4-diyl group, 2-methylhexane-2,5-diyl group, 3-methylhexane-2,5-diyl group, and 2,5-dimethylhexane-2,5-diyl group.

Specific examples of the compound of the Formula (3) include (meth)acrylamide, N,N′-dimethyl(meth)acrylamide, N,N′-diethyl(meth)acrylamide, N-[3-(dimethylamino)propyl](meth)acrylamide, N-isopropyl(meth)acrylamide, N-(hydroxymethyl)(meth)acrylamide, N-(2-hydroxyethyl)(meth)acrylamide, N-dodecyl(meth)acrylamide, diacetone(meth)acrylamide, N-tert-butyl(meth)acrylamide, N-(butoxymethyl)(meth)acrylamide, 2-(meth)acrylamide-2-methylpropanesulfonic acid, 6-(meth)acrylamide hexanoic acid, N,N′-(1,2-dihydroxyethylene)bis(meth)acrylamide, and N,N′-methylenebis(meth)acrylamide. Note that the (meth)acrylamide compound herein refers to both an acrylamide compound and a methacrylamide compound.

Among the specific examples of the compound of Formula (3), from the viewpoint of obtaining adherence by adding a very small amount thereof, N,N′-dimethyl(meth)acrylamide, N,N′-diethyl(meth)acrylamide, and N,N′-(1,2-dihydroxyethylene)bis(meth)acrylamide are preferred, and among these, N,N′-dimethylacrylamide, N,N′-diethylacrylamide, and N,N′-(1,2-dihydroxyethylene)bisacrylamide are most preferred.

The compound of the component (C) can be used alone, or two or more types can be used in combination.

The content of the component (C) in the imprint material of the present invention is 1% by mass or higher and 40% by mass or lower, for example, and preferably 5% by mass or higher and 20% by mass or lower, based on the total mass of the components (A), (B), and (C). When the content of the component (C) is lower than 1% by mass, adherence of a film obtained by photoimprint to a substrate decreases. When the content is higher than 40% by mass, abrasion resistance of the obtained film decreases.

[Component (D): Photopolymerization Initiator]

Although a photopolymerization initiator as the component (D) is not particularly limited, as long as it has absorption corresponding to a light source used for light curing. Examples of the photopolymerization initiator include organic peroxides, such as tert-butylperoxy-iso-butyrate, 2,5-dimethyl-2,5-bis(benzoyldioxy)hexane, 1,4-bis[α-(tert-butyldioxy)-iso-propoxy]benzene, di-tert-butylperoxide, 2,5-dimethyl-2,5-bis(tert-butyldioxy)hexene hydroperoxide, α-(iso-propylphenyl)-iso-propylhydroperoxide, tert-butylhydroperoxide, 1,1-bis(tert-butyldioxy)-3,3,5-trimethylcyclohexane, butyl-4,4-bis(tert-butyldioxy)valerate, cyclohexanoneperoxide, 2,2′,5,5′-tetra(tert-butylperoxycarbonyl)benzophenone, 3,3′,4,4′-tetra(tert-butylperoxycarbonyl)benzophenone, 3,3′,4,4′-tetra(tert-amylperoxycarbonyl)benzophenone, 3,3′,4,4′-tetra(tert-hexylperoxycarbonyebenzophenone, 3,3′-bis(tert-butylperoxycarbonyl)-4,4′-dicarboxybenzophenone, tert-butylperoxybenzoate, and di-tert-butyldiperoxyisophthalate; quinones, such as 9,10-anthraquinone, 1-chloroanthraquinone, 2-chloroanthraquinone, octamethylanthraquinone, and 1,2-benzanthraquinone; benzoin derivatives, such as benzoin methyl, benzoin ethyl ether, α-methylbenzoin, and α-phenylbenzoin; alkylphenone compounds, such as 2,2-dimethoxy-1,2-diphenylethan-1-one, 1-hydroxy-cyclohexyl-phenyl-ketone, 2-hydroxy-2-methyl-1-phenyl-propan-1-one, 1-[4-(2-hydroxyethoxy)-phenyl]-2-hydroxy-2-methyl-1-propan-1-one, 2-hydroxy-1-[4-{4-(2-hydroxy-2-methyl-propionyl)benzyl}-phenyl]-2-methyl-propan-1-one, phenylglyoxylic acid methyl ester, 2-methyl-1-[4-(methylthio)phenyl]-2-morpholinopropan-1-one, 2-benzyl-2-dimethylamino-1-(4-morpholinophenyl)-1-butanone, and 2-dimethylamino-2-(4-methyl-benzyl)-1-(4-morpholin-4-yl-phenyl)-butan-1-one; acylphosphine oxide compounds, such as bis(2,4,6-trimethylbenzoyl)-phenylphosphine oxide and 2,4,6-trimethylbenzoyl-diphenyl-phosphine oxide; and oxime ester compounds, such as 2-(O-benzoyloxime)-1-[4-(phenylthio)phenyl]-1,2-octanedione and 1-(O-acetyloxime)-1-[9-ethyl-6-(2-methylbenzoyl)-9H-carbazole-3-yl]ethanone.

The above-described photopolymerization initiators are commercially available, and specific examples thereof include IRGACURE (registered trademark) 651, IRGACURE 184, IRGACURE 500, IRGACURE 2959, IRGACURE 127, IRGACURE 754, IRGACURE 907, IRGACURE 369, IRGACURE 379, IRGACURE 379EG, IRGACURE 819, IRGACURE 819DW, IRGACURE 1800, IRGACURE 1870, IRGACURE 784, IRGACURE OXE01, IRGACURE OXE02, IRGACURE 250, IRGACURE 1173, IRGACURE MBF, IRGACURE 4265, and IRGACURE TPO (all of the above, manufactured by BASF Japan Ltd.); KAYACURE (registered trademark) DETX, KAYACURE MBP, KAYACURE DMBI, KAYACURE EPA, and KAYACURE OA (all of the above, manufactured by Nippon Kayaku Co., Ltd.); VICURE-10, and VICURE-55 (all of the above, manufactured by STAUFFER Co. LTD); ESACURE (registered trademark) KIP150, ESACURE TZT, ESACURE 1001, ESACURE KT046, ESACURE KB1, ESACURE KL200, ESACURE KS300, ESACURE EB3, triazine-PMS, triazine A, and triazine B (all of the above, manufactured by Nihon SiberHegner K.K.); Adeka Optomer N-1717, Adeka Optomer N-1414, and Adeka Optomer N-1606 (manufactured by ADEKA Corporation).

The photopolymerization initiator can be used alone, or two or more types can be used in combination.

The content of the component (D) in the imprint material of the present invention is 0.1 phr to 30 phr, for example, preferably 1 phr to 20 phr, and more preferably 1 phr to 8 phr, based on the total mass of the components (A), (B), and (C). When the content of the component (D) is lower than 0.1 phr, a sufficient curing property cannot be obtained, and thus patterning properties deteriorate and abrasion resistance decreases. Note that “phr” herein refers to the mass of the photopolymerization initiator as the component (D), for example, to 100 g of the total mass of the components (A), (B), and (C).

[Component (E): Silicone Compound]

The imprint material of the present invention may include a silicone compound as the component (E). The silicone compound as an optional component is a compound that has a silicone backbone (siloxane backbone) in the molecule, and preferably has a dimethyl silicone backbone in particular.

The silicone compound is commercially available, and specific examples thereof include BYK-302, BYK-307, BYK-322, BYK-323, BYK-330, BYK-333, BYK-370, BYK-375, BYK-378, BYK-UV 3500, and BYK-UV 3570 (all of the above, manufactured by BYK Japan KK); and X-22-164, X-22-164AS, X-22-164A, X-22-164B, X-22-164C, X-22-164E, X-22-163, X-22-169AS, X-22-174DX, X-22-2426, X-22-9002, X-22-2475, X-22-4952, KF-643, X-22-343, X-22-2404, X-22-2046, and X-22-1602 (all of the above, manufactured by Shin-Etsu Chemical Co., Ltd.).

The silicone compound can be used alone, or two or more types can be used in combination.

When the imprint material of the present invention contains the silicone compound as the component (E), the content thereof is preferably 0.1 phr to 15 phr, more preferably 1 phr to 10 phr, based on the total mass of the components (A), (B), and (C). If the content is lower than 0.1 phr, a sufficiently low mold release force cannot be obtained even when the silicone compound is added, and if the content is higher than 15 phr, curing may be insufficient and accordingly patterning properties may deteriorate.

[Component (F): Surfactant]

The imprint material of the present invention may contain a surfactant as the component (F). The surfactant as an optional component adjusts film-formability of a coating film to be obtained.

Examples of the surfactant include nonionic surfactants including polyoxyethylene alkylethers such as polyoxyethylene lauryl ethers, polyoxyethylene stearyl ethers, polyoxyethylene cetyl ethers, and polyoxyethylene oleyl ethers; polyoxyethylene alkylarylethers such as polyoxyethylene octyl phenyl ethers and polyoxyethylene nonyl phenyl ethers; polyoxyethylene-polyoxypropylene block copolymers; sorbitan fatty acid esters such as sorbitan monolaurates, sorbitan monopalmitates, sorbitan monostearates, sorbitan monooleates, sorbitan trioleates, and sorbitan tristearates; and polyoxyethylene sorbitan fatty acid esters such as polyoxyethylene sorbitan monolaurates, polyoxyethylene sorbitan monopalmitates, polyoxyethylene sorbitan monostearates, polyoxyethylene sorbitan trioleates, and polyoxyethylene sorbitan tristearates; fluorine-based surfactants including the product name: Eftop (registered trademark) EF301, Eftop EF303, and Eftop EF352 (Mitsubishi Materials Electronic Chemicals Co., Ltd.), the product name: MEGAFAC (registered trademark) F-171, MEGAFAC F-173, MEGAFAC F-477, MEGAFAC F-486, MEGAFAC F-554, MEGAFAC F-556, MEGAFAC R-08, MEGAFAC R-30, MEGAFAC R-30N, MEGAFAC R-40, and MEGAFAC R-40-LM (manufactured by DIC Corporation), Fluorad FC430 and Fluorad FC431 (manufactured by Sumitomo 3M Limited), the product name: AsahiGuard (registered trademark) AG710, SURFLON (registered trademark)S-382, SURFLON SC101, SURFLON SC102, SURFLON SC103, SURFLON SC104, SURFLON SC105, and SURFLON SC106 (manufactured by Asahi Glass Co., Ltd.); and organosiloxane polymer KP341 (manufactured by Shin-Etsu Chemical Co., Ltd.).

The above-described surfactant can be used alone, or two or more types can be used in combination. When the surfactant is used, the content thereof is preferably 0.01 phr to 40 phr, and more preferably 0.01 phr to 10 phr, based on the total mass of the components (A), (B), and (C).

[Component (G): Solvent]

The imprint material of the present invention may contain a solvent as the component (G). The solvent as an optional component adjusts viscosities of the components (A), (B), and (C).

Examples of the solvent include toluene, p-xylene, o-xylene, styrene, ethylene glycol dimethyl ether, propylene glycol monomethyl ether, ethylene glycol monomethyl ether, propylene glycol monoethyl ether, ethylene glycol monoethyl ether, ethylene glycol monoisopropyl ether, ethylene glycol methyl ether acetate, propylene glycol monomethyl ether acetate, ethylene glycol ethyl ether acetate, diethylene glycol dimethyl ether, propylene glycol monobutyl ether, ethylene glycol monobutyl ether, diethylene glycol diethyl ether, dipropylene glycol monomethyl ether, diethylene glycol monomethyl ether, dipropylene glycol monoethyl ether, diethylene glycol monoethyl ether, triethylene glycol dimethyl ether, diethylene glycol monoethyl ether acetate, diethylene glycol, 1-octanol, ethylene glycol, hexylene glycol, diacetone alcohol, furfuryl alcohol, tetrahydrofurfuryl alcohol, propylene glycol, benzyl alcohol, 1,3-butanediol, 1,4-butanediol, 2,3-butanediol, γ-butyrolactone, acetone, methyl ethyl ketone, methyl isopropyl ketone, diethyl ketone, methyl isobutyl ketone, methyl n-butyl ketone, cyclohexanone, 2-heptanone, ethyl acetate, isopropyl acetate, n-propyl acetate, isobutyl acetate, n-butyl acetate, ethyl lactate, ethyl pyruvate, methanol, ethanol, isopropanol, tert-butanol, allyl alcohol, n-propanol, 2-methyl-2-butanol, isobutanol, n-butanol, 2-methyl-1-butanol, 1-pentanol, 2-methyl-1-pentanol, 2-ethylhexanol, trimethylene glycol, 1-methoxy-2-butanol, isopropyl ether, 1,4-dioxane, N,N-dimethylformamide, N,N-dimethylacetamide, N-methyl-2-pyrrolidone, 1,3-dimethyl-2-imidazolidinone, dimethyl sulfoxide, and N-cyclohexyl-2-pyrrolidine. The solvent is not particularly limited, as long as it can adjust viscosities of the components (A), (B), and (C).

The solvent can be used alone, or two or more types can be used in combination. When the solvent is used, a solid content that is defined as a remaining content obtained by excluding the solvent of the component (G) from all components of the imprint material of the present invention, that is, all components including the components (A) to (C) and other additives described later, is preferably contained at 20% by mass to 80% by mass, and preferably at 40% by mass to 60% by mass to the total mass of the imprint material of the present invention.

[Other Additives]

The imprint material of the present invention can contain an epoxy compound, a photo acid generator, a photosensitizer, an ultraviolet absorber, an antioxidant, an adhesion aid, or a mold release improving agent as necessary, as long as the effects of the present invention are not impaired.

Examples of the epoxy compound include EPOLEAD (registered trademark) GT-401, EPOLEAD PB3600, CELLOXIDE (registered trademark) 2021P, CELLOXIDE 2000, CELLOXIDE 3000, EHPE 3150, EHPE 3150CE, and CYCLOMER (registered trademark) M100 (all of the above, manufactured by Daicel Corporation); and EPICLON (registered trademark) 840, EPICLON 840-S, EPICLON N-660, and EPICLON N-673-80M (all of the above, manufactured by DIC Corporation).

Examples of the photo acid generator include IRGACURE (registered trademark) PAG103, IRGACURE PAG108, IRGACURE PAG121, IRGACURE PAG203, and IRGACURE CGI725 (all of the above, manufactured by BASF Japan Ltd.); WPAG-145, WPAG-170, WPAG-199, WPAG-281, WPAG-336, and WPAG-367 (all of the above, manufactured by Wako Pure Chemical Industries, Ltd.); and TFE triazine, TME-triazine, MP-triazine, dimethoxy triazine, TS-91, and TS-01 (manufactured by SANWA Chemical Co., Ltd.).

Examples of the photosensitizer include thioxanthenes, xanthenes, ketones, thiopyrylium salts, base styryls, merocyanines, 3-substituted coumarins, 3,4-substituted coumarins, cyanines, acridines, thiazines, phenothiazines, anthracenes, coronenes, benzanthracenes, perylenes, ketocoumarins, coumarins, and borates. The photosensitizer can be used alone, or two or more types can be used in combination. UV absorption wavelengths can be adjusted by using the photosensitizer.

Examples of the ultraviolet absorber include TINUVIN (registered trademark) PS, TINUVIN 99-2, TINUVIN 109, TINUVIN 328, TINUVIN 384-2, TINUVIN 400, TINUVIN 405, TINUVIN 460, TINUVIN 477, TINUVIN 479, TINUVIN 900, TINUVIN 928, TINUVIN 1130, TINUVIN 111FDL, TINUVIN 123, TINUVIN 144, TINUVIN 152, TINUVIN 292, TINUVIN 5100, TINUVIN 400-DW, TINUVIN 477-DW, TINUVIN 99-DW, TINUVIN 123-DW, TINUVIN 5050, TINUVIN 5060, and TINUVIN 5151 (all of the above, BASF Japan Ltd.). The ultraviolet absorber can be used alone, or two or more types can be used in combination. By using the ultraviolet absorber, when light curing is performed, the cure rate of the outermost surface of a film can be controlled and thus mold release may be improved.

Examples of the antioxidant include IRGANOX (registered trademark) 1010, IRGANOX 1035, IRGANOX 1076, IRGANOX 1135, and IRGANOX 1520L (all of the above, BASF Japan Ltd.). The above-described antioxidant can be used alone, or two or more types can be used in combination. By using the antioxidant, yellow discoloration of a film by oxidation can be prevented.

Examples of the adhesion aid include 3-methacryloxypropyltrimethoxysilane and 3-acryloxypropyltrimethoxysilane. By using the adhesion aid, adherence to a base material is improved. A content of the adhesion aid is preferably 5 phr to 50 phr, and more preferably 10 phr to 50 phr based on the total mass of the components (A), (B), and (C).

Examples of the mold release improving agent include fluorine-containing compounds. Examples of the fluorine-containing compound include R-5410, R-1420, M-5410, M-1420, E-5444, E-7432, A-1430, and A-1630 (all of the above, manufactured by Daikin Industries, Ltd.).

[Preparation of Imprint Material]

A method for preparing the imprint material of the present invention is not particularly limited. In the method, the components (A), (B), (C), and (D); the components (E), (F), and (G) as optional components; and other additives if desired are mixed so that the imprint material becomes homogeneous. The order of mixing the components (A) to (G) and other additives if desired is not particularly limited, as long as a homogeneous imprint material can be obtained. In an example of the preparation method, the components (A), (B), and (C) and optionally the component (E) are mixed at predetermined percentages, and further the component (D) and optionally the components (F) and (G) are suitably mixed therein to obtain a homogeneous imprint material. In another example of the preparation method, other additives are further added and mixed therein at an appropriate step of the preparation method as necessary.

[Photoimprint and Pattern-Transferred Film]

The imprint material of the present invention can be applied onto a base material, and light-cured to obtain a desired cured film. Examples of application methods include pubicly or generally known methods, such as a spin coating method, a dip method, a flow coating method, an ink-jet method, a spray method, a bar coating method, a gravure coating method, a slit coating method, a roll coating method, a transferring printing method, brush coating, a blade coating method, and an air knife coating method.

Examples of the base material onto which the imprint material of the present invention is applied include base materials comprising silicon; glass on which a film of an indium tin oxide (ITO) is formed (hereinafter, abbreviated as “ITO substrate”); glass on which a film of a silicon nitride (SiN) is formed (SiN substrate); glass on which a film of an indium zinc oxide (IZO) is formed; polyethylene terephthalates (PET); triacetyl celluloses (TAC); acryls; plastics; glass; quartz; or ceramics. Also, flexible base materials, such as base materials comprising triacetyl celluloses, polyethylene terephthalates, polymethyl methacrylates, cycloolefin (co)polymers, polyvinylalcohols, polycarbonates, polystyrene, polyimides, polyamides, polyolefins, polypropylenes, polyethylenes, polyethylene naphthalates, or polyether sulfones; and comprising copolymers in which these polymers are combined can also be used.

The light source used for curing the imprint material of the present invention is not particularly limited, and examples thereof include high-pressure mercury lamps, low-pressure mercury lamps, electrodeless lamps, metal halide lamps, KrF excimer lasers, ArF excimer lasers, F₂ excimer lasers, electron beams (EB), and extreme ultraviolet (EUV). Generally, the wavelengths that can be used are a G-line of 436 nm, an H-line of 405 nm, an I-line of 365 nm, and a GHI-mixed line. In addition, the amount of exposure is preferably 30 mJ/cm² to 2,000 mJ/cm², and more preferably 30 mJ/cm² to 1,000 mJ/cm².

When a solvent of the component (G) is used, a baking step can be applied to at least one of a coating film before light irradiation or a film after light irradiation, in order to evaporate the solvent. An instrument for baking is not particularly limited, as long as heating under suitable atmosphere, that is, under air, an inert gas such as nitrogen, or under vacuum, is possible by using, for example, a hot plate, an oven, or a furnace. A baking temperature is not particularly limited for the purpose of evaporation of the solvent, and the baking can be performed at, for example, 40° C. to 200° C.

A device for performing photoimprint is not particularly limited, as long as a desired pattern is obtained. Examples of the device include commercially available devices such as ST50 manufactured by TOSHIBA MACHINE Co., Ltd., Sindre (registered trademark) 60 manufactured by Obducat Technologies AB, and NM-0801HB manufactured by MEISYO KIKO Co., Ltd. A method can be used in which a base material and a mold are roller-pressed by using the device, light curing is performed, and then the mold is released.

Examples of a mold material for photoimprinting used in the present invention include quartz, silicon, nickel, alumina, carbonyl silane, and glassy carbon, but not particularly limited thereto, as long as a desired pattern is obtained. A mold release treatment in which a thin film of a fluorine compound or the like is formed on the surface of a mold may be performed, in order to improve mold release. Examples of a mold release agent used for a mold release treatment include OPTOOL (registered trademark) HD and OPTOOL DSX, manufactured by Daikin Industries, Ltd., but not particularly limited thereto, as long as a desired pattern is obtained.

The pattern size of the photoimprint is on a nanometer order, and specifically follows a pattern size of less than 1 micron.

A film thus produced from the imprint material of the present invention, on which a pattern is transferred; a semiconductor element having the film; and an optical component, a solid-state image sensing element, an LED device, a solar cell, a display, and an electronic device, having the films on their base materials are also included in the present invention.

### EXAMPLES

Hereinafter, the present invention will be explained in further detail with Examples and Comparative Examples; however, the present invention is not limited to these Examples.

### Preparation of Imprint Material

### Example 1

An imprint material PNI-a1 was prepared by mixing 2 g of NK ester A-TMPT (hereinafter, abbreviated as “A-TMPT”) (manufactured by Shin Nakamura Chemical Co., Ltd.), 7 g of NK ester A-200 (hereinafter, abbreviated as “A-200”) (manufactured by Shin Nakamura Chemical Co., Ltd.), and 1 g of N,N′-dimethylacrylamide (hereinafter, abbreviated as “DMAA”) (manufactured by KJ Chemicals Corporation), and adding thereto 0.25 g (2.5 phr to the total mass of A-TMPT, A-200, and DMAA) of IRGACURE (registered trademark) TPO (manufactured by BASF Japan Ltd.) (hereinafter, abbreviated as “IRGACURE TPO”).

### Example 2

An imprint material PNI-a2 was prepared by mixing 1.9 g of A-TMPT, 7 g of A-200, 0.1 g of NK Economer A-1000PER (hereinafter, abbreviated as “A-1000PER”) (manufactured by Shin Nakamura Chemical Co., Ltd.), and 1 g of DMAA, and adding thereto 0.25 g (2.5 phr to the total mass of A-TMPT, A-200, A-1000PER, and DMAA) of IRGACURE TPO.

### Example 3

An imprint material PNI-a3 was prepared by mixing 3 g of A-TMPT, 6 g of A-200, and 1 g of DMAA, and adding thereto 0.25 g (2.5 phr to the total mass of A-TMPT, A-200, and DMAA) of IRGACURE TPO.

### Example 4

An imprint material PNI-a4 was prepared by mixing 2.9 g of A-TMPT, 6 g of A-200, 0.1 g of A-1000PER, and 1 g of DMAA, and adding thereto 0.25 g (2.5 phr to the total mass of A-TMPT, A-200, A-1000PER, and DMAA) of IRGACURE TPO.

### Example 5

An imprint material PNI-a5 was prepared by mixing 2.5 g of A-TMPT, 6 g of A-200, 0.5 g of A-1000PER, and 1 g of DMAA, and adding thereto 0.25 g (2.5 phr to the total mass of A-TMPT, A-200, A-1000PER, and DMAA) of IRGACURE TPO.

### Example 6

An imprint material PNI-a6 was prepared by mixing 2 g of A-TMPT, 7 g of A-200, 1 g of DMAA, and 0.1 g (1 phr to the total mass of A-TMPT, A-200, and DMAA) of BYK-333 (manufactured by BYK Japan KK), and adding thereto 0.25 g (2.5 phr to the total mass of A-TMPT, A-200, and DMAA) of IRGACURE TPO.

### Example 7

An imprint material PNI-a7 was prepared by mixing 1.9 g of A-TMPT, 7 g of A-200, 0.1 g of A-1000PER, 1 g of DMAA, and 0.1 g (1 phr to the total mass of A-TMPT, A-200, A-1000PER, and DMAA) of BYK-333, and adding thereto 0.25 g (2.5 phr to the total mass of A-TMPT, A-200, A-1000PER, and DMAA) of IRGACURE TPO.

### Example 8

An imprint material PNI-a8 was prepared by mixing 3 g of A-TMPT, 6 g of A-200, 1 g of DMAA, and 0.1 g (1 phr to the total mass of A-TMPT, A-200, and DMAA) of BYK-333, and adding thereto 0.25 g (2.5 phr to the total mass of A-TMPT, A-200, and DMAA) of IRGACURE TPO.

### Example 9

An imprint material PNI-a9 was prepared by mixing 2.9 g of A-TMPT, 6 g of A-200, 0.1 g of A-1000PER, 1 g of DMAA, and 0.1 g (1 phr to the total mass of A-TMPT, A-200, A-1000PER, and DMAA) of BYK-333, and adding thereto 0.25 g (2.5 phr to the total mass of A-TMPT, A-200, A-1000PER, and DMAA) of IRGACURE TPO.

### Example 10

An imprint material PNI-a10 was prepared by mixing 2.5 g of A-TMPT, 6 g of A-200, 0.5 g of A-1000PER, 1 g of DMAA, and 0.1 g (1 phr to the total mass of A-TMPT, A-200, A-1000PER, and DMAA) of BYK-333, and adding thereto 0.25 g (2.5 phr to the total mass of A-TMPT, A-200, A-1000PER, and DMAA) of IRGACURE TPO.

### Example 11

An imprint material PNI-all was prepared by mixing 2 g of A-TMPT, 7 g of A-200, 1 g of DMAA, and 0.1 g (1 phr to the total mass of A-TMPT, A-200, and DMAA) of BYK-UV3570 (manufactured by BYK Japan KK), and adding thereto 0.25 g (2.5 phr to the total mass of A-TMPT, A-200, and DMAA) of IRGACURE TPO.

### Example 12

An imprint material PNI-a12 was prepared by mixing 2 g of A-TMPT, 7 g of A-200, 1 g of DMAA, and 0.5 g (5 phr to the total mass of A-TMPT, A-200, and DMAA) of BYK-UV3570, and adding thereto 0.25 g (2.5 phr to the total mass of A-TMPT, A-200, and DMAA) of IRGACURE TPO.

### Example 13

An imprint material PNI-a13 was prepared by mixing 2 g of A-TMPT, 7 g of A-200, 1 g of DMAA, and 1 g (10 phr to the total mass of A-TMPT, A-200, and DMAA) of BYK-UV3570, and adding thereto 0.25 g (2.5 phr to the total mass of A-TMPT, A-200, and DMAA) of IRGACURE TPO.

### Example 14

An imprint material PNI-a14 was prepared by mixing 1.9 g of A-TMPT, 7 g of A-200, 0.1 g of A-1000PER, 1 g of DMAA, and 0.1 g (1 phr to the total mass of A-TMPT, A-200, A-1000PER, and DMAA) of BYK-UV3570, and adding thereto 0.25 g (2.5 phr to the total mass of A-TMPT, A-200, A-1000PER, and DMAA) of IRGACURE TPO.

### Example 15

An imprint material PNI-a15 was prepared by mixing 1.9 g of A-TMPT, 7 g of A-200, 0.1 g of A-1000PER, 1 g of DMAA, and 0.5 g (5 phr to the total mass of A-TMPT, A-200, A-1000PER, and DMAA) of BYK-UV3570, and adding thereto 0.25 g (2.5 phr to the total mass of A-TMPT, A-200, A-1000PER, and DMAA) of IRGACURE TPO.

### Example 16

An imprint material PNI-a16 was prepared by mixing 1.9 g of A-TMPT, 7 g of A-200, 0.1 g of A-1000PER, 1 g of DMAA, and 1 g (10 phr to the total mass of A-TMPT, A-200, A-1000PER, and DMAA) of BYK-UV3570, and adding thereto 0.25 g (2.5 phr to the total mass of A-TMPT, A-200, A-1000PER, and DMAA) of IRGACURE TPO.

### Example 17

An imprint material PNI-a17 was prepared by mixing 3 g of A-TMPT, 6 g of A-200, 1 g of DMAA, and 0.1 g (1 phr to the total mass of A-TMPT, A-200, and DMAA) of BYK-UV3570, and adding thereto 0.25 g (2.5 phr to the total mass of A-TMPT, A-200, and DMAA) of IRGACURE TPO.

### Example 18

An imprint material PNI-a18 was prepared by mixing 3 g of A-TMPT, 6 g of A-200, 1 g of DMAA, and 0.5 g (5 phr to the total mass of A-TMPT, A-200, and DMAA) of BYK-UV3570, and adding thereto 0.25 g (2.5 phr to the total mass of A-TMPT, A-200, and DMAA) of IRGACURE TPO.

### Example 19

An imprint material PNI-a19 was prepared by mixing 3 g of A-TMPT, 6 g of A-200, 1 g of DMAA, and 1 g (10 phr to the total mass of A-TMPT, A-200, and DMAA) of BYK-UV3570, and adding thereto 0.25 g (2.5 phr to the total mass of A-TMPT, A-200, and DMAA) of IRGACURE TPO.

### Example 20

An imprint material PNI-a20 was prepared by mixing 2.9 g of A-TMPT, 6 g of A-200, 0.1 g of A-1000PER, 1 g of DMAA, and 0.1 g (1 phr to the total mass of A-TMPT, A-200, A-1000PER, and DMAA) of BYK-UV3570, and adding thereto 0.25 g (2.5 phr to the total mass of A-TMPT, A-200, A-1000PER, and DMAA) of IRGACURE TPO.

### Example 21

An imprint material PNI-a21 was prepared by mixing 2.9 g of A-TMPT, 6 g of A-200, 0.1 g of A-1000PER, 1 g of DMAA, and 0.5 g (5 phr to the total mass of A-TMPT, A-200, A-1000PER, and DMAA) of BYK-UV3570, and adding thereto 0.25 g (2.5 phr to the total mass of A-TMPT, A-200, A-1000PER, and DMAA) of IRGACURE TPO.

### Example 22

An imprint material PNI-a22 was prepared by mixing 2.9 g of A-TMPT, 6 g of A-200, 0.1 g of A-1000PER, 1 g of DMAA, and 1 g (10 phr to the total mass of A-TMPT, A-200, A-1000PER, and DMAA) of BYK-UV3570, and adding thereto 0.25 g (2.5 phr to the total mass of A-TMPT, A-200, A-1000PER, and DMAA) of IRGACURE TPO.

### Example 23

An imprint material PNI-a23 was prepared by mixing 2.5 g of A-TMPT, 6 g of A-200, 0.5 g of A-1000PER, 1 g of DMAA, and 0.1 g (1 phr to the total mass of A-TMPT, A-200, A-1000PER, and DMAA) of BYK-UV3570, and adding thereto 0.25 g (2.5 phr to the total mass of A-TMPT, A-200, A-1000PER, and DMAA) of IRGACURE TPO.

### Example 24

An imprint material PNI-a24 was prepared by mixing 2.5 g of A-TMPT, 6 g of A-200, 0.5 g of A-1000PER, 1 g of DMAA, and 0.5 g (5 phr to the total mass of A-TMPT, A-200, A-1000PER, and DMAA) of BYK-UV3570, and adding thereto 0.25 g (2.5 phr to the total mass of A-TMPT, A-200, A-1000PER, and DMAA) of IRGACURE TPO.

### Example 25

An imprint material PNI-a25 was prepared by mixing 2.5 g of A-TMPT, 6 g of A-200, 0.5 g of A-1000PER, 1 g of DMAA, and 1 g (10 phr to the total mass of A-TMPT, A-200, A-1000PER, and DMAA) of BYK-UV3570, and adding thereto 0.25 g (2.5 phr to the total mass of A-TMPT, A-200, A-1000PER, and DMAA) of IRGACURE TPO.

### Example 26

An imprint material PNI-a26 was prepared by mixing 2 g of A-TMPT, 7 g of A-200, 1 g of DMAA, and 0.5 g (5 phr to the total mass of A-TMPT, A-200, and DMAA) of BYK-UV3570, and adding thereto 0.5 g (5 phr to the total mass of A-TMPT, A-200, and DMAA) of IRGACURE TPO.

### Example 27

An imprint material PNI-a27 was prepared by mixing 1.9 g of A-TMPT, 7 g of A-200, 0.1 g of A-1000PER, 1 g of DMAA, and 0.5 g (5 phr to the total mass of A-TMPT, A-200, A-1000PER, and DMAA) of BYK-UV3570, and adding thereto 0.5 g (5 phr to the total mass of A-TMPT, A-200, A-1000PER, and DMAA) of IRGACURE TPO.

### Example 28

An imprint material PNI-a28 was prepared by mixing 3 g of A-TMPT, 6 g of A-200, 1 g of DMAA, and 0.5 g (5 phr to the total mass of A-TMPT, A-200, and DMAA) of BYK-UV3570, and adding thereto 0.5 g (5 phr to the total mass of A-TMPT, A-200, and DMAA) of IRGACURE TPO.

### Example 29

An imprint material PNI-a29 was prepared by mixing 2.9 g of A-TMPT, 6 g of A-200, 0.1 g of A-1000PER, 1 g of DMAA, and 0.5 g (5 phr to the total mass of A-TMPT, A-200, A-1000PER, and DMAA) of BYK-UV3570, and adding thereto 0.5 g (5 phr to the total mass of A-TMPT, A-200, A-1000PER, and DMAA) of IRGACURE TPO.

### Example 30

An imprint material PNI-a30 was prepared by mixing 2.5 g of A-TMPT, 6 g of A-200, 0.5 g of A-1000PER, 1 g of DMAA, and 0.5 g (5 phr to the total mass of A-TMPT, A-200, A-1000PER, and DMAA) of BYK-UV3570, and adding thereto 0.5 g (5 phr to the total mass of A-TMPT, A-200, A-1000PER, and DMAA) of IRGACURE TPO.

### Example 31

An imprint material PNI-a31 was prepared by mixing 2 g of A-TMPT, 7 g of A-200, 1 g of DMAA, 0.1 g (1 phr to the total mass of A-TMPT, A-200, and DMAA) of BYK-333, and 0.5 g (5 phr to the total mass of A-TMPT, A-200, and DMAA) of BYK-UV3570, and adding thereto 0.5 g (5 phr to the total mass of A-TMPT, A-200, and DMAA) of IRGACURE TPO.

### Example 32

An imprint material PNI-a32 was prepared by mixing 1.9 g of A-TMPT, 7 g of A-200, 0.1 g of A-1000PER, 1 g of DMAA, 0.1 g (1 phr to the total mass of A-TMPT, A-200, A-1000PER, and DMAA) of BYK-333, and 0.5 g (5 phr to the total mass of A-TMPT, A-200, A-1000PER, and DMAA) of BYK-UV3570, and adding thereto 0.5 g (5 phr to the total mass of A-TMPT, A-200, and DMAA) of IRGACURE TPO.

### Example 33

An imprint material PNI-a33 was prepared by mixing 3 g of A-TMPT, 6 g of A-200, 1 g of DMAA, 0.1 g (1 phr to the total mass of A-TMPT, A-200, and DMAA) of BYK-333, and 0.5 g (5 phr to the total mass of A-TMPT, A-200, and DMAA) of BYK-UV3570, and adding thereto 0.5 g (5 phr to the total mass of A-TMPT, A-200, and DMAA) of IRGACURE TPO.

### Example 34

An imprint material PNI-a34 was prepared by mixing 2.9 g of A-TMPT, 6 g of A-200, 0.1 g of A-1000PER, 1 g of DMAA, 0.1 g (1 phr to the total mass of A-TMPT, A-200, A-1000PER, and DMAA) of BYK-333, and 0.5 g (5 phr to the total mass of A-TMPT, A-200, A-1000PER, and DMAA) of BYK-UV3570, and adding thereto 0.5 g (5 phr to the total mass of A-TMPT, A-200, A-1000PER, and DMAA) of IRGACURE TPO.

### Example 35

An imprint material PNI-a35 was prepared by mixing 2.5 g of A-TMPT, 6 g of A-200, 0.5 g of A-1000PER, 1 g of DMAA, 0.1 g (1 phr to the total mass of A-TMPT, A-200, A-1000PER, and DMAA) of BYK-333, and 0.5 g (5 phr to the total mass of A-TMPT, A-200, A-1000PER, and DMAA) of BYK-UV3570, and adding thereto 0.5 g (5 phr to the total mass of A-TMPT, A-200, A-1000PER, and DMAA) of IRGACURE TPO.

### Example 36

An imprint material PNI-a36 was prepared by mixing 2.5 g of A-TMPT, 6 g of A-200, 0.5 g of A-1000PER, 1 g of DMAA, and 0.5 g (5 phr to the total mass of A-TMPT, A-200, A-1000PER, and DMAA) of BYK-UV3570, and adding thereto 0.1 g (1 phr to the total mass of A-TMPT, A-200, A-1000PER, and DMAA) of IRGACURE TPO.

### Example 37

An imprint material PNI-a37 was prepared by mixing 2.5 g of A-TMPT, 6.5 g of A-200, 1 g of DMAA, and 0.5 g (5 phr to the total mass of A-TMPT, A-200, A-1000PER, and DMAA) of BYK-UV3570, and adding thereto 0.1 g (1 phr to the total mass of A-TMPT, A-200, A-1000PER, and DMAA) of IRGACURE TPO.

### Example 38

An imprint material PNI-a38 was prepared by mixing 2.5 g of A-TMPT, 6.5 g of A-200, 1 g of DMAA, and 0.5 g (5 phr to the total mass of A-TMPT, A-200, A-1000PER, and DMAA) of BYK-UV3570, and adding thereto 0.5 g (5 phr to the total mass of A-TMPT, A-200, A-1000PER, and DMAA) of IRGACURE TPO.

### Example 39

An imprint material PNI-a39 was prepared by mixing 2.5 g of A-TMPT, 6 g of A-200, 0.5 g of A-1000PER, 1 g of DMAA, and 0.5 g (5 phr to the total mass of A-TMPT, A-200, A-1000PER, and DMAA) of BYK-UV3570, and adding thereto 0.1 g (1 phr to the total mass of A-TMPT, A-200, A-1000PER, and DMAA) of IRGACURE (registered trademark) 819 (manufactured by BASF Japan Ltd.) (hereinafter, abbreviated as “IRGACURE 819”).

### Example 40

An imprint material PNI-a40 was prepared by mixing 2.5 g of A-TMPT, 6.5 g of A-200, 1 g of DMAA, and 0.5 g (5 phr to the total mass of A-TMPT, A-200, A-1000PER, and DMAA) of BYK-UV3570, and adding thereto 0.1 g (1 phr to the total mass of A-TMPT, A-200, A-1000PER, and DMAA) of IRGACURE 819.

### Example 41

An imprint material PNI-a41 was prepared by mixing 2.5 g of A-TMPT, 6 g of A-200, 0.5 g of A-1000PER, 1 g of DMAA, and 0.5 g (5 phr to the total mass of A-TMPT, A-200, A-1000PER, and DMAA) of BYK-UV3570, and adding thereto 0.5 g (5 phr to the total mass of A-TMPT, A-200, A-1000PER, and DMAA) of IRGACURE 819.

### Comparative Example 1

An imprint material PNI-b1 was prepared by mixing 3.0 g of KAYARAD (registered trademark) PET30 (hereinafter, abbreviated as “PET30”) (manufactured by Nippon Kayaku Co., Ltd.), 6.0 g of A-200, and 1 g of DMAA, and adding thereto 0.25 g (2.5 phr to the total mass of PET30, A-200, and DMAA) of IRGACURE TPO.

### Comparative Example 2

An imprint material PNI-b2 was prepared by mixing 3.0 g of PET30, 6.0 g of A-200, 1 g of DMAA, and 0.1 g (1 phr to the total mass of PET30, A-200, and DMAA) of BYK-333, and adding thereto 0.25 g (2.5 phr to the total mass of PET30, A-200, and DMAA) of IRGACURE TPO.

### Comparative Example 3

An imprint material PNI-b3 was prepared by mixing 3.0 g of PET30, 6.0 g of A-200, 1 g of DMAA, and 0.1 g (I phr to the total mass of PET30, A-200, and DMAA) of BYK-UV3570, and adding thereto 0.25 g (2.5 phr to the total mass of PET30, A-200, and DMAA) of IRGACURE TPO.

### Comparative Example 4

An imprint material PNI-b4 was prepared by mixing 3.0 g of KAYARAD (registered trademark) DPHA (hereinafter, abbreviated as “DPHA”) (manufactured by Nippon Kayaku Co., Ltd.), 6.0 g of A-200, and 1 g of DMAA, and adding thereto 0.25 g (2.5 phr to the total mass of DPHA, A-200, and DMAA) of IRGACURE TPO.

### Comparative Example 5

An imprint material PNI-b5 was prepared by mixing 3.0 g of DPHA, 6.0 g of A-200, 1 g of DMAA, and 0.1 g (1 phr to the total mass of DPHA, A-200, and DMAA) of BYK-333, and adding thereto 0.25 g (2.5 phr to the total mass of DPHA, A-200, and DMAA) of IRGACURE TPO.

### Comparative Example 6

An imprint material PNI-b6 was prepared by mixing 3.0 g of DPHA, 6.0 g of A-200, 1 g of DMAA, and 0.1 g (1 phr to the total mass of DPHA, A-200, and DMAA) of BYK-UV3570, and adding thereto 0.25 g (2.5 phr to the total mass of DPHA, A-200, and DMAA) of IRGACURE TPO.

### Comparative Example 7

An imprint material PNI-b7 was prepared by mixing 6.5 g of A-200 and 3.5 g of A-1000PER, and adding thereto 0.25 g (2.5 phr to the total mass of A-200 and A-1000PER) of IRGACURE TPO.

[Mold Release Treatment]

A moth-eye patterned nickel mold (manufactured by InnoX Co., Ltd.) with a pitch of 250 nm and a height of 250 nm and a silicon wafer were immersed in a solution obtained by diluting OPTOOL (registered trademark) DSX (manufactured by Daikin Industries, Ltd.) in NOVEC (registered trademark) HFE-7100 (hydrofluoroether, Sumitomo 3M Limited) (hereinafter, abbreviated as “NOVEC HFE-7100”) to 0.1% by mass, treated for 1 hour with a high-temperature and high-humidity apparatus at a temperature of 90° C., and a humidity of 90 RH %, rinsed with NOVEC HFE-7100, and then air-dried.

[Photoimprint]

Each of the imprint materials obtained in Examples 1 to 41 and Comparative Examples 1 to 7 was applied onto a triacetyl cellulose film having a thickness of 60 μm (FUJITAC (registered trademark) manufactured by Fujifilm Corporation was used) (hereinafter, abbreviated as “TAC film”) by using a bar coater (a full automatic film applicator KT-AB3120, manufactured by Kotec Ltd.). Each resulting coating film on the TAC film was roller-pressed on the moth-eye patterned mold that had been subjected to the above-described mold release treatment. Subsequently, the coating film was exposed to light at 350 mJ/cm² from the TAC film side by using an electrodeless uniform illumination device (QRE-4016A, manufactured by ORC Manufacturing Co., Ltd.) to be light-cured, and then the TAC film was peeled from the moth-eye patterned mold. Thus, a cured film on which a concavity and convexity shape of the moth-eye patterned mold was transferred was obtained.

[Adherence Test]

Adherence of each obtained cured film to the TAC film was tested. This adherence test was performed following the procedure below in accordance with JIS K5400.

To begin with, grid-shaped cuts reaching the TAC film were made in the cured film with a cutter so that 100 cells at 1 mm intervals were provided. An adhesive cellophane tape with a length of approximately 50 mm was attached on the grid-shaped cells, and instantaneously peeled off at an angle of 90° with respect to the film surface. After peeling off the tape, the cells were observed, the number of cells, out of 100 cells, from which the film had not been peeled off was denoted by x, and the adherence was evaluated as x/100. The adherence test was repeated three times, and the average value of the respective evaluations was calculated.

[Steel-Wool Abrasion Test]

On each obtained cured film, a steel-wool abrasion test was performed. A test machine manufactured by Daiei Seiki Ltd. was used, and a steel wool of #0000 was used. The load per unit area was set at 15 g/cm², the steel wool was reciprocated 10 times, and the number of scratches formed after the abrasion was observed. This abrasion test was repeated three times, and the average value of the numbers of scratches was calculated and was rated as follows.

0 to 1 scratch: A

2 to 5 scratches: B

6 to 10 scratches: C

11 or more scratches: D

[Test for Resistance to Damp-Cloth Wiping]

The surface of each cured film on which a concavity and convexity shape had been transferred was rubbed with water-containing BEMCOT M-1 (manufactured by Asahi Kasei Fibers Corp.). Subsequently, fluorescent light was radiated on the cured film from the TAC film side thereof to determine whether haze, which was caused by adherence of adjacent convex portions to each other in the concavity and convexity shape, was present by visual observation from a direction tilted at 30° with respect to the cured film. The obtained results are listed in Tables 1 and 2.

TABLE 1

| | | Abrasion | Presence |
|---|---|---|---|
| | Adherence | Resistance | of Haze |
| Example 1 | 100/100 | B | No |
| Example 2 | 100/100 | B | No |
| Example 3 | 100/100 | B | No |
| Example 4 | 100/100 | B | No |
| Example 5 | 100/100 | B | No |
| Example 6 | 100/100 | A | No |
| Example 7 | 100/100 | A | No |
| Example 8 | 100/100 | A | No |
| Example 9 | 100/100 | A | No |
| Example 10 | 100/100 | A | No |
| Example 11 | 100/100 | B | No |
| Example 12 | 100/100 | A | No |
| Example 13 | 100/100 | A | No |
| Example 14 | 100/100 | B | No |
| Example 15 | 100/100 | A | No |
| Example 16 | 100/100 | A | No |
| Example 17 | 100/100 | B | No |
| Example 18 | 100/100 | A | No |
| Example 19 | 100/100 | A | No |
| Example 20 | 100/100 | B | No |
| Example 21 | 100/100 | A | No |
| Example 22 | 100/100 | A | No |
| Example 23 | 100/100 | B | No |
| Example 24 | 100/100 | A | No |
| Example 25 | 100/100 | A | No |

TABLE 2

| | | Abrasion | Presence |
|---|---|---|---|
| | Adherence | Resistance | of Haze |
| Example 26 | 100/100 | A | No |
| Example 27 | 100/100 | A | No |
| Example 28 | 100/100 | A | No |
| Example 29 | 100/100 | A | No |
| Example 30 | 100/100 | A | No |
| Example 31 | 100/100 | A | No |
| Example 32 | 100/100 | A | No |
| Example 33 | 100/100 | A | No |
| Example 34 | 100/100 | A | No |
| Example 35 | 100/100 | A | No |
| Example 36 | 100/100 | A | No |
| Example 37 | 100/100 | B | No |
| Example 38 | 100/100 | B | No |
| Example 39 | 100/100 | A | No |
| Example 40 | 100/100 | A | No |
| Example 41 | 100/100 | A | No |
| Comparative | 10/100 | D | No |
| Example 1 | | | |
| Comparative | 4/100 | D | No |
| Example 2 | | | |
| Comparative | 4/100 | D | No |
| Example 3 | | | |
| Comparative | 7/100 | D | No |
| Example 4 | | | |
| Comparative | 5/100 | D | No |
| Example 5 | | | |
| Comparative | 0/100 | D | No |
| Example 6 | | | |
| Comparative | 20/100 | B | Yes |
| Example 7 | | | |

The results listed in Tables 1 and 2 show that all of the cured films obtained by using the imprint materials prepared in Examples 1 to 41 were excellent in adherence to the TAC films, that abrasion resistance was confirmed based on the small numbers of scratches, ranging from 0 to 5, formed after the steel-wool abrasion tests, and that resistance to damp-cloth wiping was confirmed since adjacent convex portions in a concavity and convexity shape could be prevented from adhering to each other even when a surface on which the concavity and convexity shape had been transferred was wiped with a damp cloth. In contrast, the results show that the cured films obtained by using the imprint materials prepared in Comparative Examples 1 to 6 had many scratches after the steel-wool abrasion tests, and lacked adherence to the TAC films. The results also show that the cured film obtained by using the imprint material prepared in Comparative Example 7 lacked adherence to the TAC film, and when a surface thereof on which a concavity and convexity shape had been transferred was wiped with a damp cloth, adjacent convex portions in the concavity and convexity shape adhered to each other. As described above, the cured film obtained from the imprint material of the present invention has excellent adherence to a substrate, has abrasion resistance, and also has excellent resistance to damp-cloth wiping.

1. An imprint material comprising:
a component (A);
a component (B);
a component (C); and
a component (D) below, wherein
(A): a compound of Formula (1) below,
(B): a compound of Formula (2) below,
(C): a compound of Formula (3) below, and
(D): a photopolymerization initiator, 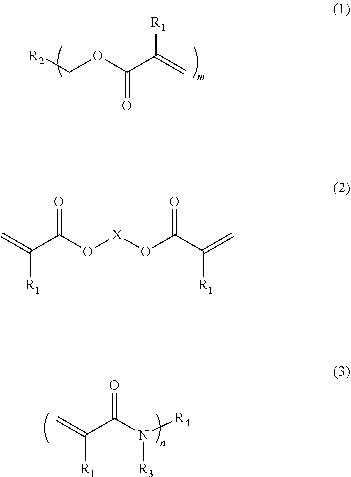
wherein, each R₁ is independently a hydrogen atom or a methyl group, R₂ is a C₁₋₅ hydrocarbon group that optionally has a hydroxy group as a substituent, m is 2 or 3, X is a divalent linking group having an ethylene oxide unit and/or a propylene oxide unit, R₃ is a hydrogen atom or a C₁₋₃ alkyl group, n is 1 or 2, and
when n is 1, R₄ is a C₁₋₁₂ alkyl group that is optionally substituted with at least one substituent selected from the group consisting of hydroxy group, carboxy group, acetyl group, amino group in which one or two hydrogen atoms are optionally substituted with a methyl group, sulfo group, and a C₁₋₄ alkoxy group, and
when n is 2, R₄ is a C₁₋₁₂ alkylene group that is optionally substituted with at least one substituent selected from the group consisting of hydroxy group, carboxy group, acetyl group, amino group in which one or two hydrogen atoms are optionally substituted with a methyl group, sulfo group, and a C₁₋₄ alkoxy group.

2. The imprint material according to claim 1, wherein
the component (B) contains one or two compounds of Formula (2a): 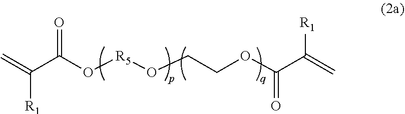
wherein, each R₁ is independently a hydrogen atom or a methyl group, R₅ is a trimethylene group or a propylene group, and each of p and q is independently an integer of 0 or more and satisfies a relational expression of 1≤(p+q)≤30.

3. The imprint material according to claim 1, wherein content of the component (A) is 10% by mass or higher and 40% by mass or lower, based on total mass of the component (A), the component (B), and the component (C).

4. The imprint material according to claim 1, wherein content of the component (C) is 1% by mass or higher and 40% by mass or lower, based on total mass of the component (A), the component (B), and the component (C).

5. The imprint material according to claim 1, further comprising a silicone compound as a component (E).

6. The imprint material according to claim 1, further comprising a surfactant as a component (F).

7. The imprint material according to claim 1, further comprising a solvent as a component (G).

8. A method for producing a film on which a pattern is transferred, the method comprising the steps of:
forming a film by applying the imprint material as claimed in claim 1 onto a base material; and
transferring the pattern onto the film by using a photoimprint device, bringing a mold on which a pattern is formed into contact with the film, further pressing the film against the mold, subsequently light-curing the film, and then releasing the mold from the film.
